(19) United States
(12) Patent Application Publication
(10) Pub. No.: US 2009/0218606 A1
(43) Pub. Date: Sep. 3, 2009

(54) VERTICALLY INTEGRATED LIGHT SENSOR AND ARRAYS

(76) Inventors: Nathaniel J. McCaffrey, Hampton Falls, NH (US); James E. Carey, Waltham, MA (US); Stephen Saylor, South Hamilton, MA (US)

Correspondence Address: PEPPER HAMILTON LLP, ONE MELLON CENTER, 50TH FLOOR, 500 GRANT STREET, PITTSBURGH, PA, 15219, US

(21) Appl. No.: 12/396,170

(22) Filed: Mar. 2, 2009

Related U.S. Application Data
(60) Provisional application No. 61/032,630, filed on Feb. 29, 2008.

(51) Int. Cl. H01L 31/112; H01L 31/103; H01L 27/146

(52) U.S. Cl. 257/292; 257/461; 257/443; 257/E31.079; 257/E31.057; 257/E27.133

(57) ABSTRACT

Embodiments hereof include a photosensing device, comprising an isolation layer; a photodetector layer comprising a plurality of pixels, wherein the photodetector layer is in contact with a first side of the isolation layer, wherein the photodetector layer comprises a laser-processed semiconductor material; and a semiconductor layer disposed on a second side of the isolation layer.

### CROSS-REFERENCE TO RELATED APPLICATIONS

The present application claims the benefit of U.S. provisional application No. 61/032,630 filed on Feb. 28, 2009, hereby incorporated by reference in its entirety, and is related to PCT/US/09/35538 filed on Feb. 27, 2009.

### TECHNICAL FIELD

The present disclosure generally relates to methods and systems for making and using photodetectors and arrays of photodetectors. More particularly, the present disclosure relates to methods and systems for increasing the fill factor and photon acceptance cone for pixels of a photodetector, and the arrangement and configuration of said photodetectors and pixels.

### BACKGROUND

Conventional silicon wafers require a substantial absorption depth for photons having wavelengths longer than approximately 500 nm. For example, conventional silicon wafers having a standard wafer depth (approximately 850 μm) cannot absorb photons having wavelengths in excess of 1050 nm.

As such, designing pixels using conventional silicon requires a deep collection element for photons that have a wavelength greater than approximately 500 nm. If photons incident upon a surface of the wafer and traveling into its depth are absorbed in a region deeper than the effective field of these pixel elements, the absorbed photons can generate photoelectrons that wander (diffuse) to adjacent pixels causing cross talk and lower resolution. In photodetector arrays, and in applications using the same, this can result in a blurring effect and a loss of accuracy in spatially-dependent applications such as imaging equipment. Such wandering photoelectrons in field-free regions also have a higher probability of recombining before pixel collection resulting in lower sensitivity and efficiency.

For imaging applications, such as mobile phone cameras, digital still cameras, video cameras, and the like, picture elements or “pixels” are designed to capture photons effectively at up to several microns in depth. For longer wavelength applications, such as automotive, security and medical imaging cameras, pixel capture depths arc designed to be in the tens or hundreds of microns. The relationship between light wavelength 110 (“A.”) and absorption depth 120 in silicon is depicted in FIG. 1. The acceptance cone includes an incident angle of light from the primary lens to the pixel element. In conventional imagers, the aspect ratio (height of the bus stack to the photodiode dimension) exceeds 1:1 and because of this, the incident light angle is often limited to approximately 20 degrees. Reduced acceptance cone angles in the sensor design increases the height of, for example, a camera by dictating the overall acceptance cone angle and corresponding distance from the imager to the primary lens. Thinner cameras are generally desired. In some application areas, such as for mobile phone cameras, thinner embodiments are a critical design parameter.

FIG. 3 illustrates a conventional pixel 300 having an acceptance cone angle 310 of approximately 22 degrees. It can therefore be appreciated that at least in imaging applications the geometry of conventional pixel designs limits the performance of the pixels and the overall imaging apparatus. Conventional approaches to achieve smaller pixels have disadvantages. Maintaining sensitivity while reducing pixel size conventionally requires the implementation of reduced design rules for more narrow bus lines. For example, a voltage reduction is typically required to implement such designs. This reduces the depth of detector depletions and can eventually compromise sensitivity and spectral response. Pixel dimension reduction requirements have outpaced the reduction in thickness of the bus stack and the aspect ratio has increased resulting in the reduction of both fill factor and acceptance cone angle.

FIG. 4 depicts a chip-level layout of a conventional CMOS imaging device 400. As shown in FIG. 4, typical imaging circuits 400 used for cameras on a chip place processing and readout circuits adjacent to the pixel array area 405. Other functional elements, such as pixel power 410, row decode 415, column multiplexing 420, timing and control 425, coding and communication 430, and analog to digital conversion 435 are performed on other areas of the imaging device 400. The layout of the imaging device 400 is at least in part determined based on the absorption depth required for the pixel array 405 for the particular application for which it is designed. The imaging device 400 is sometimes manufactured as an integrated circuit (“IC”) or a semiconductor-based chip.

In some cases, the pixel array area 405 may be placed on a semiconductor material that is positioned above the remainder of the imaging circuit. This may be done, for example, when the pixel array area 405 is made of a different semiconductor material, such as Indium Gallium Arsenide (InGaAs), than the remainder of the imaging circuit 400, which is typically made of Silicon (Si). However, even when the pixel array area 405 is arranged in this manner, the portion of a conventional imaging circuit 400 underneath the pixel array area 405 is merely used for electrically passing the signal to the lower semiconductor material and is not used for additional processing. This is because the gain in the pixel array area 405 is not sufficient to drive electrons horizontally within the semiconductor material. Since only a portion of the lower semiconductor material is used for processing operations, the functionality provided by photodetectors is limited to operations having circuitry that can fit within the surrounding material.

CMOS imaging circuit can be characterized by a “device fill factor,” corresponding to the fraction of the overall chip area being effectively devoted to the pixel array, and a “pixel fill factor,” corresponding to the effective area of a light sensitive photodiode relative to the area of the pixel that may be used to determine the amount of silicon that is photoactive. The device fill factor in conventional devices is less than unity (1.0) because, as described above, a notable portion of the device beneath the pixel array area cannot be used for processing.

Moreover, the pixel fill factor in conventional devices is typically substantially less than 1.0 because, for example, bussing and addressing circuits are fabricated around the base substrate layers of a pixel As such, the bussing and addressing circuits limit the amount of space available for photodetection circuitry. Such bussing and addressing circuitry also limit the acceptance cone angle for electrons directed towards an imaging array.

An exemplary conventional CMOS imaging circuit commonly used in the industry, the MT9T001 CMOS Digital Image Sensor from Micron Technology, Inc., has a pixel fill factor of approximately 28% and a device fill factor of approximately 57%. As such, approximately 0.28 times 0.57, i.e. 16% of the semiconductor material of a conventional CMOS imaging circuit is photoactive. In other words, approximately 84% of a CMOS imaging circuit is used for purposes other than the primary purpose of the circuit, which is photodetection. This inefficiency leads to unwanted increased size of the overall product and cost of the product as well as degraded performance of the product made from the conventional photodetector array. An improved photodetector and array is needed that overcomes some or all of the above-mentioned disadvantages.

### SUMMARY

This disclosure provides detailed preferred and exemplary and alternative embodiments of the concepts disclosed and described herein, but is not limited to the particular systems, devices and methods or embodiments described, as these may vary. Embodiments hereof include a photosensing device, comprising an isolation layer; a photodetector layer comprising a plurality of pixels, wherein the photodetector layer is in contact with a first side of the isolation layer, wherein the photodetector layer comprises a laser-processed semiconductor; and a silicon layer disposed on a second side of the isolation layer.

### BRIEF DESCRIPTION OF THE DRAWINGS

To better illustrate and explain certain aspects, features, benefits and advantages of the present concepts, exemplary embodiments are shown in the accompanying drawings, in which:

FIG. 1 illustrates absorption depths for multi-spectral photons in conventional silicon photodetectors;

FIG. 2 illustrates a cross sectional view of a conventional advanced pixel for a photodetector array;

FIG. 3 illustrates a conventional pixel designed at the base level with advanced design rules;

FIG. 4 illustrates a chip-level layout of a conventional CMOS imaging circuit according to the known art;

FIG. 5 illustrates an architectural structure for an exemplary vertically integrated pixel array according to an embodiment;

FIGS. 6A-C illustrate contact layouts for exemplary lateral photodetectors according to embodiments;

FIG. 7A illustrates a circuit diagram for an exemplary lateral photoconductive MOS active pixel using a photodiodic element;

FIG. 7B illustrates a circuit diagram for an exemplary lateral photoconductive MOS active pixel using a photoresistive element;

FIGS. 8A-B illustrate contact layouts for exemplary vertical photodetectors according to embodiments; and

FIG. 9 illustrates a chip-level layout of a vertically integrated imager according to an embodiment.

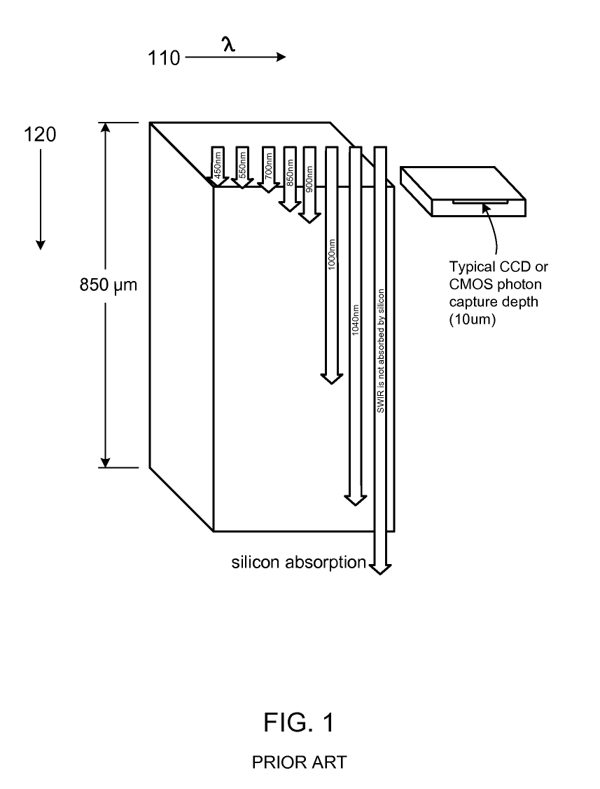

### DETAILED DESCRIPTION

The following terms shall have, for the purposes of this application, the respective meanings set forth below. “Device fill factor” refers to the area of an imaging pixel array on an imaging chip divided by the overall chip area. The device fill factor for an imaging chip is affected by the placement of circuitry that supports the imaging pixel array. “Laser-processed semiconductor” refers to a semiconductor having high energy density fields. A laser-processed semiconductor is produced by using an ultra-fast laser to create high energy density fields in small areas within the laser's beam profile. Laser-processed semiconductor materials are effective at enhancing the sensitivity and spectral range of photonic devices. Ultra-fast lasers, such as lasers capable of producing femtosecond and/or nanosecond pulses, can be used to create very high energy density fields at a semiconductor surface. These conditions ablate the surface, and the ultra-fast duration of the laser pulse localizes these effects to a small area that is generally within the beam profile for the laser. The reformed material may include dopants that were present in a laser processing chamber during the ablation process and the semiconductor materials modified through these structural and chemical changes. For example, the semiconductor material may be irradiated in the presence of a sulfur-containing gas. Exemplary laser-processed semiconductors are discussed in U.S. Pat. No. 7,057,256 to Carey et al.

“Pixel fill factor” refers to the area of a pixel that is dedicated to photon collection divided by the total area of the pixel. A laser-processed semiconductor pixel may be fabricated as the top layer in an integrated circuit provided that the conditions to form the pixel (i.e., heat and/or light) can be isolated from adversely affecting lower layers. A blocking or isolation layer comprising metals and/or oxides may be placed above the top silicon layer in order to prevent the heat and light from affecting that silicon layer. The shallow detection and absorption properties of laser-processed semiconductors simultaneously shields light from sensitive circuits placed on the silicon layers beneath the photodetector and the isolation layer and efficiently converts the light into useful electrical signals.

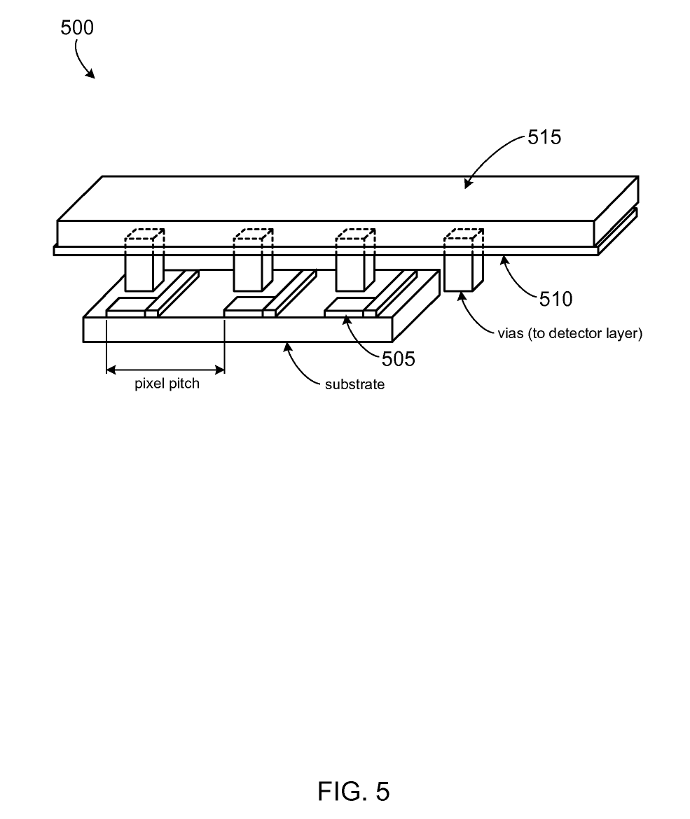

FIG. 5 illustrates an architectural structure for an exemplary vertically integrated pixel array 500 according to an embodiment hereof. An integrated circuit (“IC”) may be designed to amplify, process and readout a sampled charge at regularly arranged sample sites (i.e., pixels). Such circuits are generally designed on multiple layers on the surface of a semiconductor (i.e., the base layers 505). A planarization process may create an isolation layer 510 upon which a semiconductor photodetector layer 515 can be grown or deposited in crystalline, polycrystalline or amorphous forms.

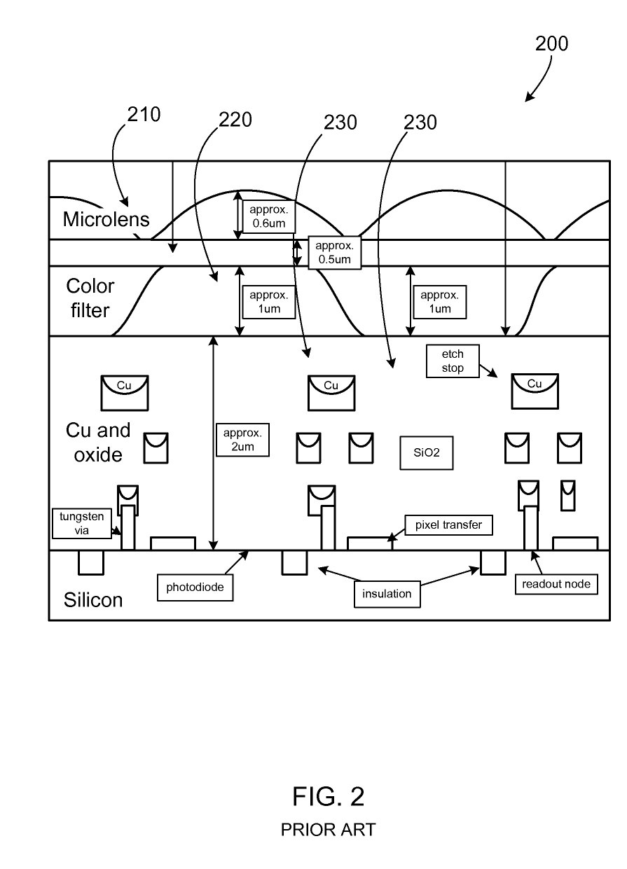

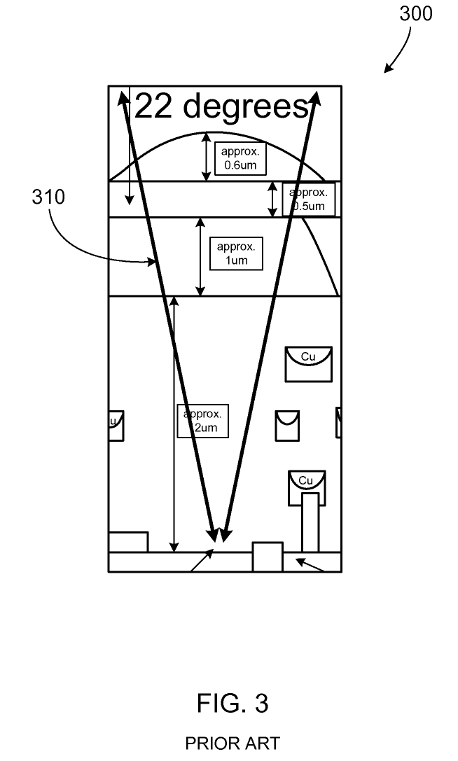

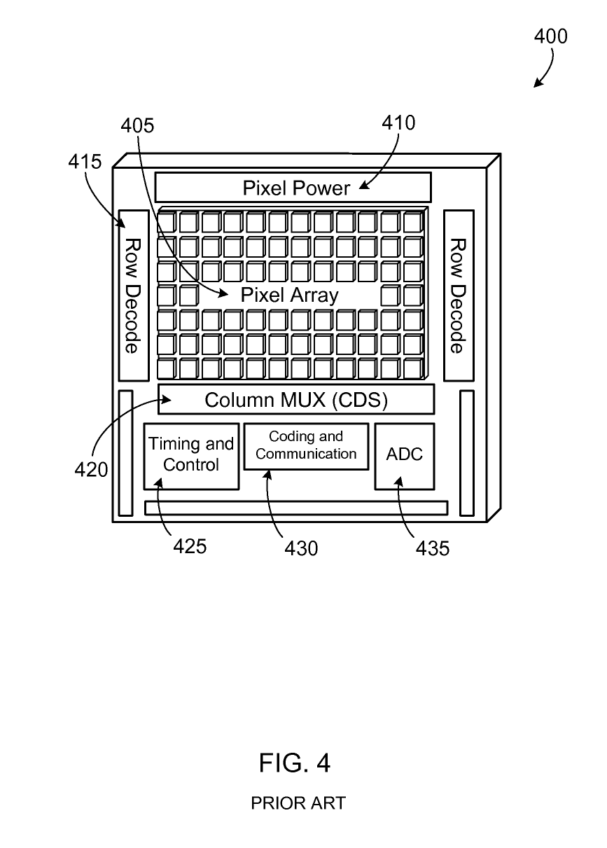

In an embodiment, the isolation layer 510 may include an electrically and thermally insulative material, such as silicon dioxide. An insulative isolation layer 510 may be used with one or more vias 520 to conduct electrical signals from the photodetector layer 515 to the base layers 505. In an alternate embodiment, the isolation layer 510 may include an electrically conductive material, such as aluminum. The electrically conductive isolation layer 510 may operate as both a blocking layer during laser processing and a circuit element in an operational layer for a common plate on a metal-insulator-metal (MIM) capacitor field for pixel signal storage. By organizing the imaging array in this manner, optical system design and performance may be positively affected. Conventional imaging arrays for which pixels are designed at the base level with advanced design rules require photons to traverse a multi-metal stack with many oxide interfaces before being detected, as was shown in FIG. 2 above. The conventional pixel fill factor for such advanced pixels is typically less than 35%, and the acceptance cone (i.e., the maximum angle at which light received by the photodetector layer can be utilized) for photons is typically less than 25 degrees. An exemplary pixel, shown in FIG. 3 above, has a pixel fill factor of 28% and an acceptance cone of 22 degrees.

In contrast, according to some embodiments, by placing the photodetector layer above the remaining circuitry that is present on the base layer, a greater pixel fill factor, e.g., greater than 90% and sometimes even almost 100%, and a greater acceptance cone, e.g., greater than 90 degrees, and sometimes even greater than 150 degrees, and still even almost approximately 180 degrees in some embodiments, may be achieved.

In one or more embodiments, the device fill factor may be greater than approximately 80%. A device designed with an architecture corresponding to the present disclosure may enable, for example, a smaller device and/or a device having additional features or functionality that can be achieved in a form factor equal to or smaller than conventional devices.

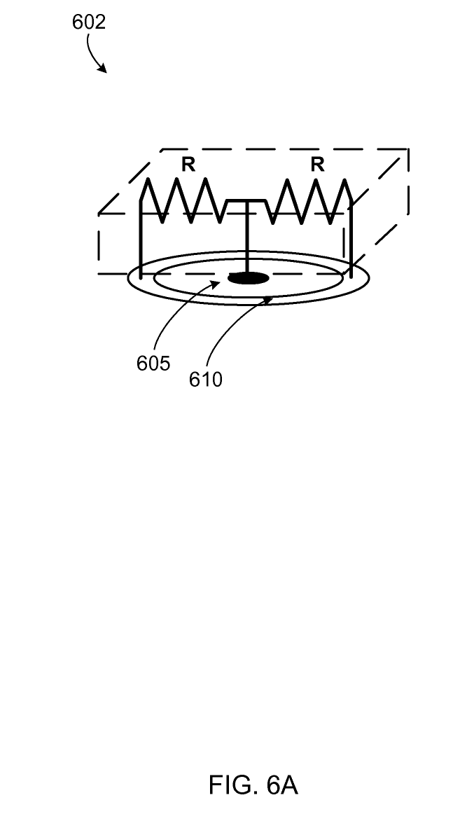

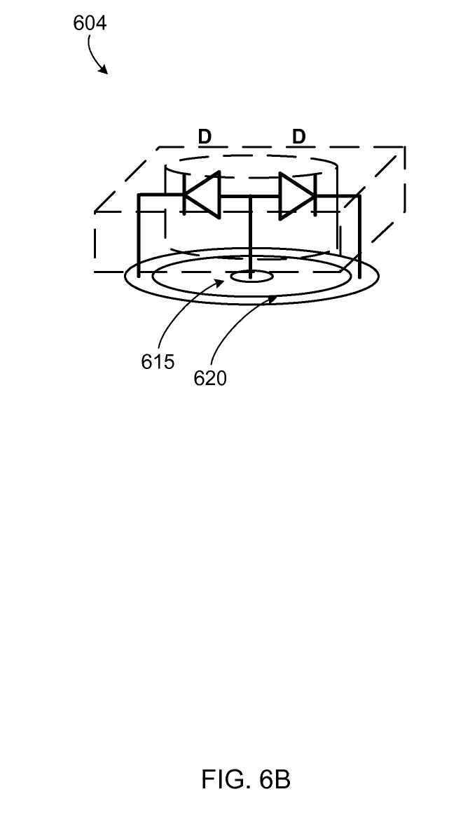

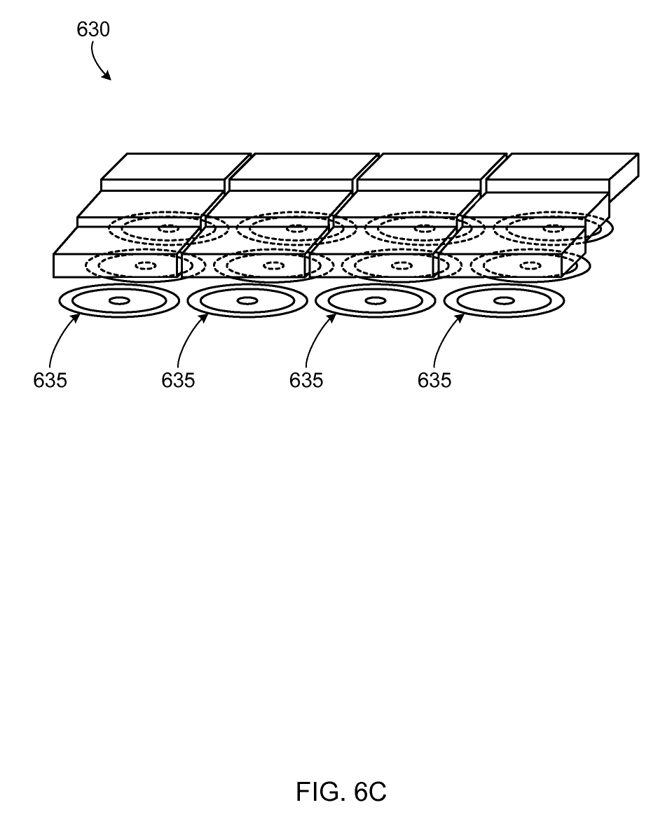

FIGS. 6A-C illustrate contact layouts for exemplary lateral photo resistors 602, photodiodes 604 and phototransistors according to one or more embodiments. Integration and storage of the pixel photocharge may be performed under the photoconductive layer. The photodetector may be maintained under constant conditions (fixed voltage or current) to provide enhanced linearity and uniformity. Connections between the photodetector and the underlying device layers may be achieved using vias fabricated from a refractory metal, such as tungsten or tantalum. Placing storage elements under the photoconductors may provide many photonic benefits. For example, the entire pixel array may be dedicated to signal processing. This may enable higher performance by permitting access to the low level pixel signals. Furthermore, massively parallel operations may be performed by pixel processors. For example, analog to digital conversion, noise reduction (Le., true correlated double sampling), power conditioning, nearest neighbor pixel processing, compression, fusion, and color multiplexing operations may be performed.

As shown in FIGS. 6A-C, lateral photodetectors may be developed into imaging arrays without any top level metals. Two vias arranged in concentric patterns, such as 605 and 610 in FIG. 6A or 615 and 620 in FIG. 6B, may provide low crosstalk with neighboring pixels (not shown) and good uniformity across pixel area. Of course, other geometries than those shown may also be used, for example as nested rectangular shaped areas. Because the lateral photodetectors of FIGS. 6A-6C do not require top level metals, which can block light from being received, an improved pixel fill factor, e.g., approximately 100% and an improved acceptance cone, e.g. approximately 180 degrees, may be achieved by such photodetectors. FIG. 6C illustrates an exemplary regular arrangement of the photodetectors of FIG. 6A or 6B as they would appear in a substantially two-dimensional array 630 for use in an exemplary product. The elements 635 of the array 630 can be arranged in Cartesian, honeycomb, or other geometrical relationship with one another.

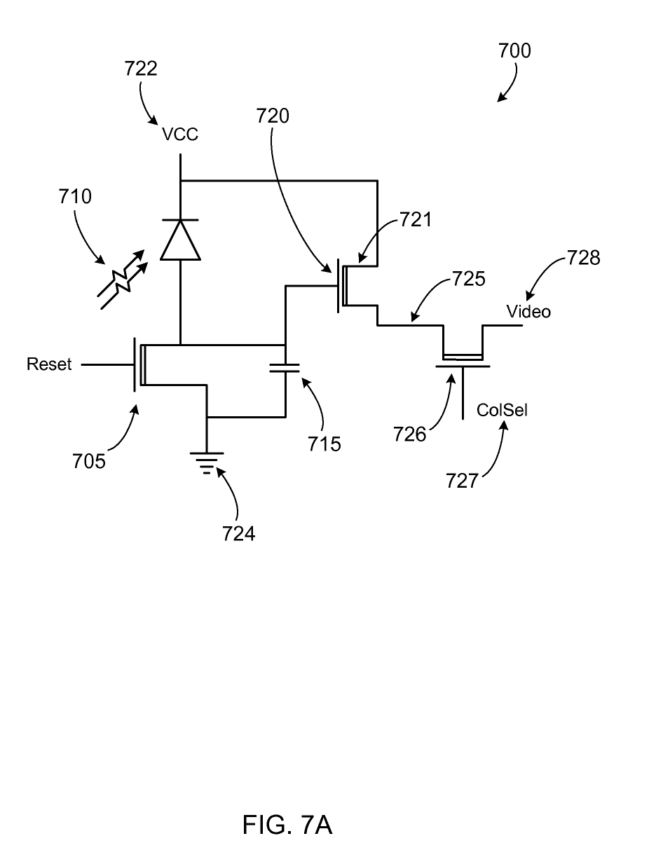

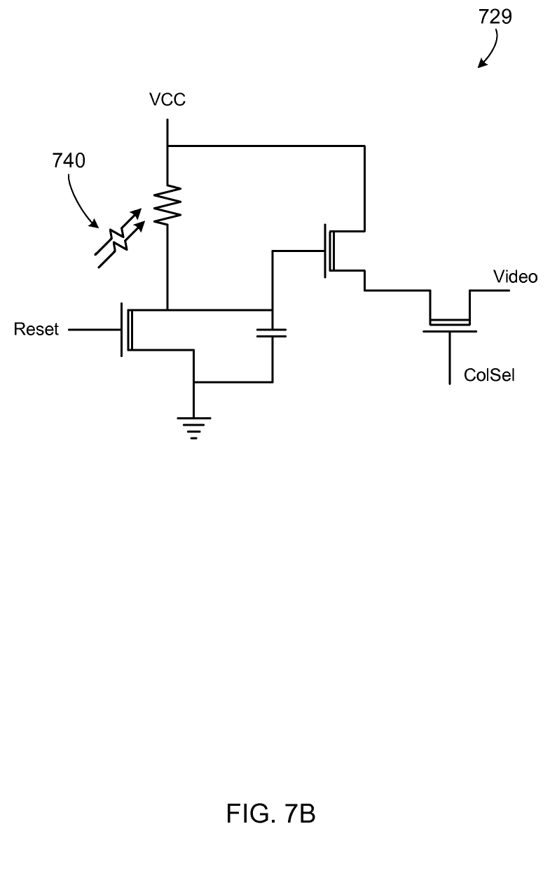

FIG. 7A depicts an illustrative circuit diagram of an exemplary lateral photoconductive MOS active pixel using a photodiodic element. As shown in FIG. 7A, the active pixel 700 may include a first transistor 705, a photodiodic element 710, a capacitive element 715, a second transistor 720 and a third transistor 725. The Grst transistor 705 may have its gate connected to a Reset signal, its drain connected to ground, and its source connected to an anode of the photodiodic element 710, a first side of the capacitive element 715 and the gate 720 of the second transistor. The photodiodic element 710 may further have its cathode connected to power 722. The capacitive element 715 may further have a second side connected to ground 724. The second transistor 720 may further have its source 721 connected to power 722 and its drain connected to the source 725 of the third transistor. The third transistor may further have its gate 726 connected to a column select line 727, which corresponds to a column in which the active pixel 700 is located, and its drain connected to a Video Output signal 728. FIG. 7B illustrates a circuit diagram for an exemplary lateral photoconductive MOS active pixel 729 using a resistive element. As shown in FIG. 7B, the photodiodic element 710 of FIG. 7A may be replaced with a photoresistive element 740. In an embodiment, all connections between elements in FIG. 7B may be substantially the same as those depicted in FIG. 7A except that a first lead of the photoresistive element 740 is substituted for the anode of the photodiodic clement 710 of FIG. 7A and a second lead of the photoresistive element is substituted for the cathode of the photodiodic clement. Alternate photodiodic and photoresistive MOS active pixel embodiments may be used within the scope of this disclosure.

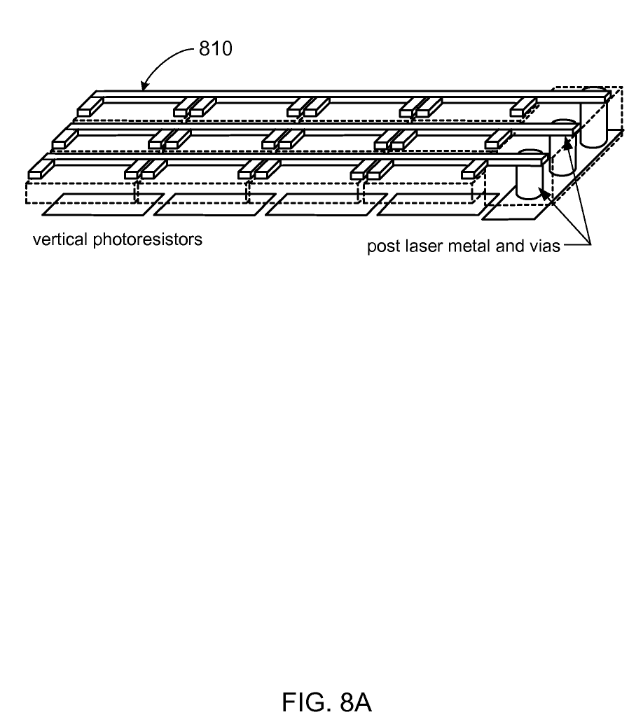

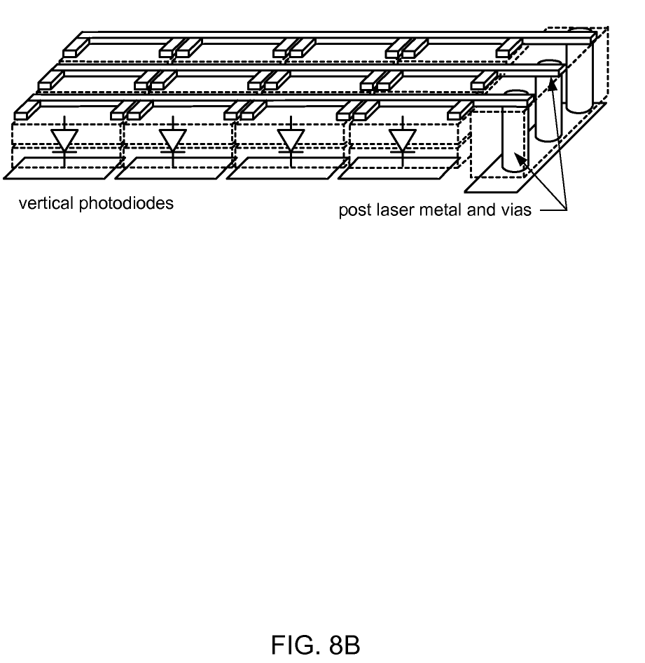

FIGS. 8A-B illustrate contact layouts for exemplary vertical photodetectors according to embodiments. As shown in FIGS. 8A-B, vertical photodetectors 805 may be developed into imaging arrays as well. A top conductor 810 may be used for each pixel. In addition, bussing to each pixel may be connected to the base layers 815 with vias 820 at, for example, the imaging area periphery. In an embodiment, the top conductor 810 may comprise a transparent electrical conductor, such as indium tin oxide (ITO). As such, the top conductor 810 may not substantially reduce the angle at which the acceptance cone for an active pixel receives light.

The top conductor 810 may be deposited on the surface of the vertical photodetectors and contacted at the periphery of the imaging area using vias 820. The use of vias 820 may enable processing circuitry to be placed directly beneath the vertical photodetectors 805. Accordingly, the base layer 815 of the imaging circuit under the photodetectors 805 need not be utilized solely for receiving information from the photodetectors. Rather, control circuits, communications circuits and other non-imaging circuits may be located directly under the photodetectors 805. The imaging array can perform complex functions with reduced semiconductor area and/or with reduced cost associated with the footprint.

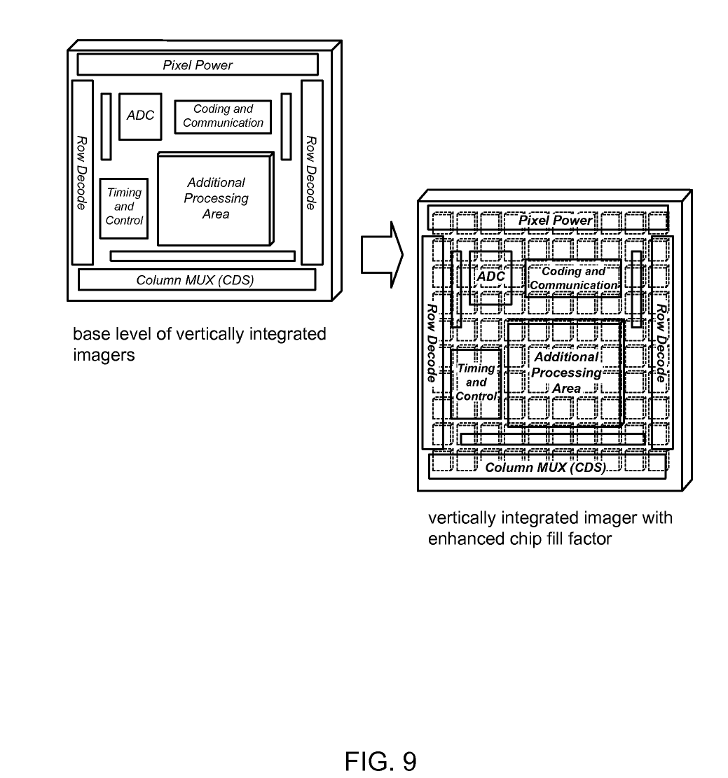

FIG. 9 depicts a chip-level layout of a vertically integrated imager according to an embodiment. Pixels developed at the top level not requiring local amplification (passive pixels) may be located over analog and digital processing circuits as opposed to conventional camera on a chip imagers, which place processing and readout circuits adjacent to the pixel array area. As shown in FIG. 9, pixels having high gain may drive video signals directly to processing circuits on a chip. Such pixels may be fabricated using a high speed laser at a location above processing and/or ancillary circuits. As such, the device fill factor is increased significantly by enabling a greater area of the silicon footprint to be photoactive. The conventional CMOS imager discussed above has a pixel fill factor of 0.28 and a device fill factor of 0.57. Accordingly, the amount of silicon that is photoactive is approximately 16%. In contrast, the device shown in FIG. 9 may have a pixel fill factor of approximately 1.00 and a device fill factor of approximately 0.84. As such, the overall photoactive area is approximately 84%. In other words, a device of FIG. 9 that is equivalent in size to a conventional CMOS imager may be designed with 525% more light gathering area. The inherent sensitivity and photoconductive gain advantages of laser-processed silicon may result in even greater advantages with this photoactive area. Alternatively, an imager of equivalent sensitivity may be designed in a much smaller area for miniature applications or lower cost devices.

It will be appreciated that various of the above-disclosed and other features and functions, or alternatives thereof, may be desirably combined into many other different systems or applications. It will also be appreciated that various presently unforeseen or unanticipated alternatives, modifications, variations or improvements therein may be subsequently made by those skilled in the art which are also intended to be encompassed by the disclosed embodiments.

What is claimed is:

1. A photosensing device, comprising:
an isolation layer;
a photodetector layer comprising a plurality of pixels, wherein the photodetector layer is in contact with a first side of the isolation layer, wherein the photodetector layer comprises a laser-processed semiconductor material; and
a semiconductor layer disposed on a second side of the isolation layer.

2. The photosensing device of claim 1 wherein the semiconductor layer is in electrical communication with the photodetector layer.

3. The photosensing device of claim 2, wherein the semiconductor layer is comprised of silicon.

4. The photosensing device of claim 1 wherein the isolation layer comprises an electrically insulative and thermally insulative material.

5. The photosensing device of claim 4 wherein the isolation layer comprises silicon dioxide.

6. The photosensing device of claim 1 wherein an optical isolation layer comprises an electrically conductive material.

7. The photosensing device of claim 6 wherein the optical isolation layer comprises aluminum.

8. The photosensing device of claim 1 wherein a pixel fill factor for the photodetector layer is greater than 90%.

9. The photosensing device of claim 1 wherein a device fill factor for the photodetector layer is greater than 80%.

10. The photosensinlg device of claim 1 wherein an acceptance cone angle for at least one pixel of the photoconductor layer is greater than 150 degrees.

11. The photosensing device of claim 1, said device comprising a plurality of readout circuits coupled to corresponding portions of said photodetector layer.

12. The photosensing device of claim 11, said photodetector layer covering an area common to said readout circuits.

13. A photosensing device, comprising:
an imaging array having a plurality of pixels, wherein the imaging array comprises a laser-processed semiconductor material;
a base layer disposed substantially beneath the imaging array, wherein the base layer comprises one or more processing circuits;
a plurality of vias in electrical communication with the base layer; and
a plurality of top conductors disposed above the imaging array, wherein a top conductor is associated with each pixel and is in electrical communication with a corresponding via.

14. The photosensing device of claim 13 wherein at least one top conductor comprises indium tin oxide.

15. The photosensing device of claim 13 wherein at least one via is disposed at an outer edge of the imaging array.

16. The photosensing device of claim 13 wherein at least one via is not disposed directly beneath the pixel corresponding to the via.

17. The photosensing device of claim 13 wherein at least one processing circuit is disposed directly beneath the imaging array.

18. A photodetector, comprising:
first, second and third transistors, wherein each transistor has a source, gate and drain;
a capacitive element having first and second plates; and
a photodiodic element having an anode and a cathode,
wherein the source of the first transistor is electrically connected to the anode of the photodiodic element, the gate of the second transistor and a first plate of the capacitive element, wherein the gate of the first transistor is electrically connected to a reset signal, wherein the drain of the first transistor and the second plate of the capacitive element are grounded, wherein the cathode of the photodiodic element and the source of the second transistor are electrically connected to power, wherein the drain of the second transistor is electrically connected to the source of the third transistor, wherein the gate of the third transistor is electrically connected to a column select signal, and wherein the source of the third transistor is electrically connected to an output signal.

19. A photodetector, comprising:
first, second and third transistors, wherein each transistor has a source, gate and drain;
a capacitive element having first and second plates; and
a photoresistive element having first and second leads,
wherein the source of the first transistor is electrically connected to the first lead of the photoresistive element, the gate of the second transistor and a first plate of the capacitive element, wherein the gate of the first transistor is electrically connected to a reset signal, wherein the drain of the first transistor and the second plate of the capacitive clement are grounded, wherein the second lead of the photoresistive element and the source of the second transistor are electrically connected to power, wherein the drain of the second transistor is electrically connected to the source of the third transistor, wherein the gate of the third transistor is electrically connected to a column select signal, and wherein the source of the third transistor is electrically connected to an output signal.

20. A photosensing device, comprising:
an isolation layer;
a-photodetector layer is in contact with a first side of the isolation layer, wherein the photodetector layer comprises a laser-processed semiconductor material; and
a semiconductor layer disposed on a second side of the isolation layer.

21. A photosensing device, comprising:
an isolation layer having a first and second side;
a semiconductor layer in contact with the first side of the isolation layer and configured that photons penetrate the semiconductor layer; and
a photodetector layer in contact with a second side of the isolation layer, wherein the photodetector layer comprises a laser-processed semiconductor material capable absorbing a portion of the photons that penetrate the semiconductor layer.
